(19) United States
(12) Patent Application Publication
(10) Pub. No.: US 2010/0046169 A1
(43) Pub. Date: Feb. 25, 2010

(54) Heat Dissipation Device Having Sound Output Function

(76) Inventor: Jennifer Hu, Taipei (TW)

Correspondence Address: LIN & ASSOCIATES INTELLECTUAL PROPERTY, INC., P.O. BOX 2339, SARATOGA, CA, 95070-0339, US

(21) Appl. No.: 12/197,313

(22) Filed: Aug. 25, 2008

(51) Int. Cl. H05K 7/20

(52) U.S. Cl. 361/707

(57) ABSTRACT

A heat dissipation device having sound output function includes a base body for placing an audio/video player thereon. The base body has an inclined surface under which a fan is disposed to dissipate out the heat generated from the audio/video player. The base body incorporates with a sound output assembly including a left channel, a right channel, a center channel, and a subwoofer channel. The base body has an audio input jack disposed at a rear side thereof for connection with an audio cable. When the audio cable is connected between the audio/video player and the audio input jack, the sound of the audio/video player can be played back through the sound output assembly to form a surround sound effect.

### BACKGROUND OF THE INVENTION

1. Field of the Invention

The present invention generally relates to a heat dissipation device for audio/video players, and more particularly, to a heat dissipation device that includes a sound output assembly with multiple channels and can be electrically connected with an audio/video player such that the sound of the audio/video player can be transmitted to the heat dissipation device and played back through the sound output assembly.

2. The Prior Arts

One commercially available notebook computer cooling pad includes a pad surface for placing a notebook computer thereon. A fan is disposed under the pad surface to effectively dissipate the heat generated from the notebook computer during operation. In addition to provide the heat dissipation function, improvements are further made in some cooling pads to design the pad surface to have an ergonomical inclined surface, thereby relieving the fatigue of a user's wrist and reducing the load on the user's cervical vertebra.

On the other hand, during the use of the cooling pad, the inventor of the present invention found out that the sound outputted by the notebook computer is typically a mono channel sound and is outputted from a mono channel of the computer, thus having no stereo sound effect. Therefore, the inventor came up with an idea that multiple sound output channels can be incorporated in the cooling pad without increasing the size of the cooling pad and the cooling pad can be electrically connected to the notebook computer such that the sound of the notebook computer can be transmitted to the cooling pad and played back through the multiple sound output channels, thereby providing a stereo sound effect. However, the heat dissipation device developed based on this concept is not intended to be limited to the application in notebook computers, but can also be used in other audio/video players such as DVD players.

### SUMMARY OF THE INVENTION

Accordingly, it is an attempt of the present invention to improve a conventional notebook computer heat dissipation device to incorporate with multiple channels such that the heat dissipation device can not only dissipate out the heat generated from the notebook computer, but also have a surround sound playback function.

In one embodiment, the present invention provides a heat dissipation device having sound output function. The heat dissipation device includes a base body for placing an audio/video player thereon. The base body has an inclined surface under which a fan is disposed to dissipate out the heat generated from the audio/video player. The base body incorporates with a sound output assembly including a left channel, a right channel, a center channel, and a subwoofer channel. The base body also has an audio input jack for connection with an audio cable. When the audio cable is connected between the audio/video player and the audio input jack, the sound of the audio/video player is played back through the sound output assembly to form a surround sound effect.

The above heat dissipation device having sound output function has an excellent heat dissipation function. The base body has an inclined surface for placing the audio/video player thereon, thus achieving an ergonomical requirement as in the conventional heat dissipation device. Furthermore, the sound of the audio/video player can be transmitted to the heat dissipation device and directly played back through the channels in the heat dissipation device, thus forming a surround sound effect without using extra speakers.

### BRIEF DESCRIPTION OF THE DRAWINGS

The present invention will be apparent to those skilled in the art by reading the following detailed description of a preferred embodiment thereof, with reference to the attached drawings, in which:

FIG. 1 is a top perspective view of a heat dissipation device having sound output function according to one embodiment of the present invention;

FIG. 2 is a bottom perspective view of the heat dissipation device having sound output function according to one embodiment of the present invention; and

FIG. 3 shows that a notebook computer is placed on the heat dissipation device of the present invention.

### DETAILED DESCRIPTION OF THE PREFERRED EMBODIMENTS

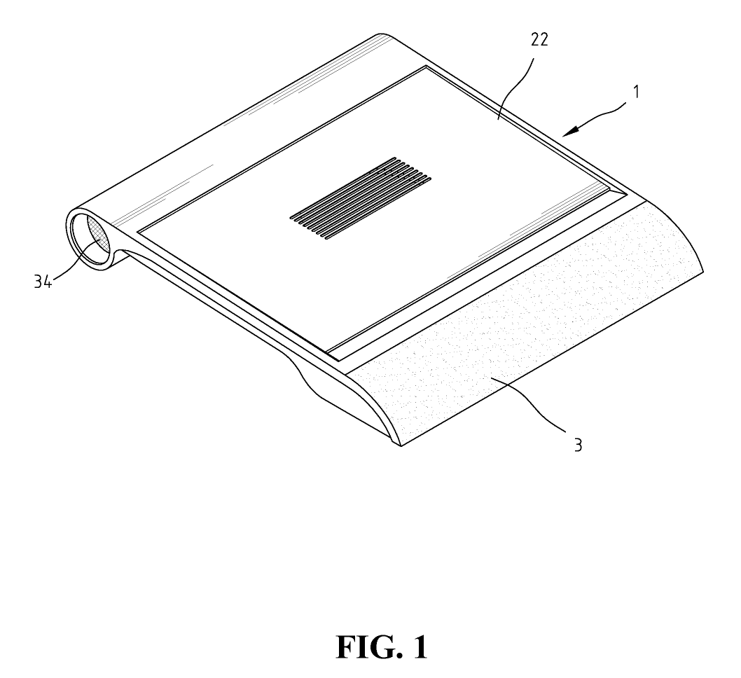

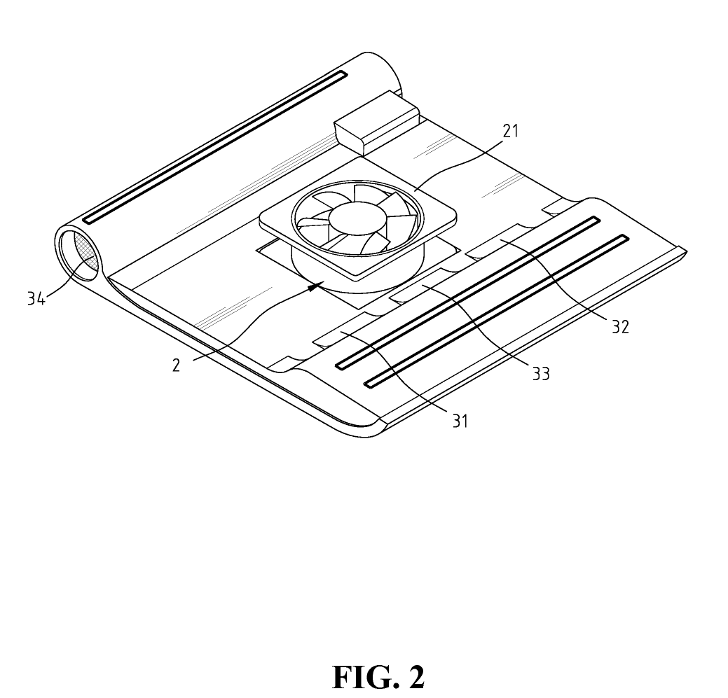

FIG. 1 and FIG. 2 are top and bottom perspective views of a heat dissipation device having sound output function according to one embodiment of the present invention. The heat dissipation device of the present invention mainly includes a base body 1 with an inclined surface. A heat dissipation unit 2 is disposed at a bottom of the base body 1, and the base body 1 incorporates with a sound output assembly 3 with multiple channels.

The base body 1 is configured to have an ergonomical inclined surface. Audio input jacks 11 are disposed on a rear side of the base body 1.

The heat dissipation unit 2 includes a fan 21 and a heat conductive plate 22 disposed on a bottom and a top surface of the base body 1, respectively.

The sound output assembly 3 include a left channel 31, a right channel 32 and a center channel 33 formed at a front side of the base body 1, and a subwoofer channel 34 formed at two sides of a rear side of the base body 1.

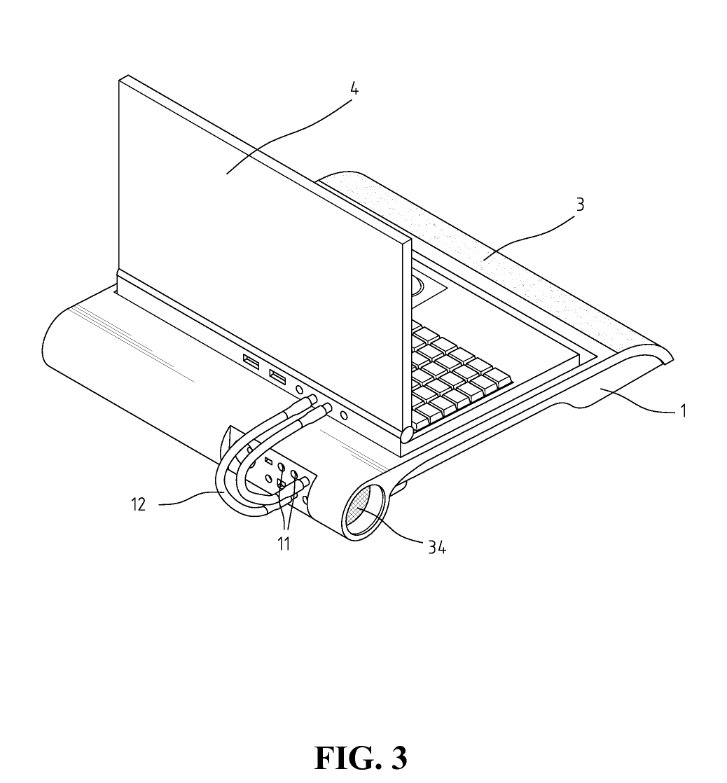

FIG. 3 shows that a notebook computer is placed on the heat dissipation device of the present invention. The inclined surface of the base body 1 is formed to place an audio/video player 4 thereon, such as a notebook computer, or a DVD, etc. A bottom of the audio/video player 4 contacts with a surface of the heat conductive plate 22. The heat generated from the audio/video player 4 can be excellently dissipated out by the fan 21. On the other hand, audio cables 12 can be connected between the audio/video player 4 and the audio input jacks 11 of the base body 1 such that the sound of the audio/video player 4 can be transmitted to the base body 1 and played back through the left channel 31, the right channel 32, the center channel 33, and the subwoofer channel 34, thereby converting an original ordinary stereo sound of the audio/video player 4 into a surround sound effect.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A heat dissipation device having sound output function comprising a base body for placing an audio/video player thereon, the base body being connected with a heat dissipation unit which is used to dissipate out the heat generated from the audio/video player, wherein the base body incorporates with a sound output assembly and an audio input jack for connection with an audio cable, and when the audio cable is connected between the audio/video player and the audio input jack, the sound of the audio/video player is played back through the sound output assembly to form a surround sound effect.

2. The heat dissipation device as claimed in claim 1, wherein the sound output assembly comprises a left channel, a right channel and a center channel disposed at one side of the base body, and a subwoofer channel disposed at another side of the base body.
